(19) United States
(12) Patent Application Publication
(10) Pub. No.: US 2019/0244843 A1
(43) Pub. Date: Aug. 8, 2019

(54) DATA PROCESSING METHOD, DATA PROCESSING APPARATUS, DATA PROCESSING SYSTEM, AND RECORDING MEDIUM HAVING RECORDED THEREIN DATA PROCESSING PROGRAM

(71) Applicant: SCREEN Holdings Co., Ltd., Kyoto (JP)

(72) Inventors: Hideji NAOHARA, Kyoto-shi (JP); Kouhei NISHIKAWA, Kyoto-shi (JP)

(21) Appl. No.: 16/261,832

(22) Filed: Jan. 30, 2019

(30) Foreign Application Priority Data
Feb. 8, 2018 (JP) 2018-020800

(51) Int. Cl. H01L 21/67; G05B 19/418; B25J 11/00

(52) U.S. Cl. CPC H01L 21/67276; G05B 19/41875; G05B 2219/50391; G05B 2219/45031; B25J 11/0095

(57) ABSTRACT

A data processing method for processing a plurality of pieces of unit-processing data (each unit-processing data includes a plurality of pieces of time series data) includes: a change timing setting step of setting change timing for reference data which is data selected from the plurality of pieces of unit-processing data and is data to be compared with each unit-processing data; and a reference data changing step of changing the reference data at the timing set in the change timing setting step.

### BACKGROUND OF THE INVENTION

### Field of the Invention

The present invention relates to digital data processing, and particularly relates to a method for processing time series data.

### Description of Related Art

As a method for detecting an abnormality of equipment or an apparatus, there is known a method of measuring a physical quantity (e.g., length, angle, time, speed, force, pressure, voltage, current, temperature, flow rate, etc.) which shows an operation state of the equipment or the apparatus by use of a sensor or the like, and analyzing time series data obtained by arranging measurement results in order of occurrence. When the equipment or the apparatus performs the same operation in the same condition, if there is no abnormality, the time series data changes in the same way. Therefore, by comparing a plurality of pieces of time series data which change in the same way to each other to detect abnormal time series data and analyzing the abnormal time series data, it is possible to specify a place where the abnormality occurs and the cause of the abnormality. Also, in recent years, computer data processing capability has been improved remarkably. There have thus been many cases where, even when an amount of data is enormous, necessary results can be obtained in practical time. This also shows that the analysis of time series data is becoming active.

For example, in a semiconductor manufacturing apparatus, time series data can be obtained in various processes. Therefore, also in the field of the semiconductor manufacturing apparatus, analysis of time series data, display of time series data on a screen, and the like, have been performed.

In connection with the present invention, Japanese Laid-Open Patent Publication No. 2017-83985 discloses an invention of a time series data processing apparatus that displays time series data in a mode easy for the user to analyze. In the time series data processing apparatus, a plurality of pieces of time series data are divided into a plurality of groups, and an abnormality degree of each group and an abnormality degree of time series data within each group are calculated. Then, a result of ranking the groups or the pieces of time series data based on the abnormality degrees is displayed on a display.

A substrate processing apparatus such as a cleaning apparatus, which is one type of the semiconductor manufacturing apparatus, generally includes a plurality of chambers (processing chambers). When the same recipe is executed in the plurality of chambers, uniform results are preferably obtained in the plurality of chambers. Hence a plurality of chambers included in one substrate processing apparatus preferably have similar processing performance. However, in reality, a difference in processing performance occurs among a plurality of chambers. For this reason, when processing is being normally performed on a substrate in a certain chamber, similar processing may not be being normally performed in another chamber.

In view of this, also in the field of substrate processing apparatuses, analysis of time series data obtained by various processes is being performed in order to achieve early detection of abnormality and prevention of abnormality. Meanwhile, in order to determine whether or not each piece of time series data included in a plurality of pieces of time series data changing in the same manner is abnormal, each piece of time series data to be evaluated is compared with time series data having ideal time-series values (data values). As time series data having the ideal time series values, for example, it is conceivable to use time series data made up of average values of a plurality of pieces of time series data. However, in a case where the plurality of pieces of time series data on which an average value is calculated include a large number of pieces of data having abnormal values or having significantly different values from the other values, a calculated average value is not necessarily an ideal value, and an abnormality thus cannot be detected accurately.

### SUMMARY OF THE INVENTION

An object of the present invention is therefore to provide a data processing method capable of performing abnormality detection using time series data more accurately than before.

One aspect of the present invention is directed to a data processing method for processing a plurality of pieces of unit-processing data by regarding a plurality of pieces of time series data obtained by unit-processing as unit-processing data, the method including:

a change timing setting step of setting change timing for reference data which is data selected from the plurality of pieces of unit-processing data and is data to be compared with each piece of unit-processing data; and a reference data changing step of changing the reference data at the timing set in the change timing setting step.

With such a configuration, it is possible to set the timing of changing the reference data selected from a plurality of pieces of unit-processing data each including a plurality of pieces of time series data. Then, the reference data is changed at the set timing. Therefore, by properly setting the change timing, it is possible to hold the reference data appropriate for the current state of system in which data processing is performed. This makes it possible to compare the obtained unit-processing data with the reference data appropriate for the current state of the system, so that the abnormality of the processing can be detected accurately. As described above, it is possible to perform the abnormality detection using time series data more accurately than before.

Another aspect of the present invention is directed to a data processing apparatus for processing a plurality of pieces of unit-processing data by regarding a plurality of pieces of time series data obtained by unit-processing as unit-processing data, the apparatus including:

a change timing setting part configured to set change timing for reference data which is data selected from the plurality of pieces of unit-processing data and is data to be compared with each piece of unit-processing data; and a reference data changing part configured to change the reference data at the timing set by the change timing setting part.

Still another aspect of the present invention is directed to a data processing system for processing a plurality of pieces of unit-processing data by regarding a plurality of pieces of time series data obtained by unit-processing as unit-processing data, the system including:

a change timing setting part configured to set change timing for reference data which is data selected from the plurality of pieces of unit-processing data and is data to be compared with each piece of unit-processing data;

a reference data changing part configured to change the reference data at the timing set by the change timing setting part.

Still another aspect of the present invention is directed to a computer-readable recording medium having recorded therein a data processing program for processing a plurality of pieces of unit-processing data by regarding a plurality of time series data obtained by unit-processing as unit-processing data, wherein the data processing program causes a computer to execute:

a change timing setting step of setting change timing for reference data which is data selected from the plurality of pieces of unit-processing data and is data to be compared with each piece of unit-processing data; and a reference data changing step of changing the reference data at the timing set in the change timing setting step.

These and other objects, features, modes, and advantages of the present invention will become more apparent from the following detailed description of the present invention with reference to the accompanying drawings.

### BRIEF DESCRIPTION OF THE DRAWINGS

FIG. 1 is a diagram showing a schematic configuration of a substrate processing system according to a first embodiment of the present invention.

FIG. 2 is a diagram showing a schematic configuration of a substrate processing apparatus according to the first embodiment.

FIG. 3 is a diagram representing a certain time series data by a graph.

FIG. 4 is a diagram for explaining unit-processing data in the first embodiment.

FIG. 5 is a block diagram showing a hardware configuration of a controller of the substrate processing apparatus in the first embodiment.

FIG. 6 is a diagram for explaining time series data DB in the first embodiment.

FIG. 7 is a diagram for explaining reference data DB in the first embodiment.

FIG. 8 is a block diagram showing a hardware configuration of a management server in the first embodiment.

FIG. 9 is a flowchart showing a procedure of data processing concerning change in the reference data in the first embodiment.

FIG. 10 is a view showing an example of a change timing setting screen in the first embodiment.

FIG. 11 is a diagram for explaining determination as to whether or not a change designation date has been reached in the first embodiment.

FIG. 12 is a diagram for explaining a change in the change designation date associated with a setting change for change timing in the first embodiment.

FIG. 13 is a flowchart showing a procedure of the unit-processing data evaluation processing in the first embodiment.

FIG. 14 is a view showing an example of a scoring screen in the first embodiment.

FIG. 15 is a view showing an example of a scoring result list screen in the first embodiment.

FIG. 16 is a view for explaining transition of the scoring result list screen at the time of recommendation setting in the first embodiment.

FIG. 17 is a view for explaining the transition of the scoring result list screen at the time of recommendation setting in the first embodiment.

FIG. 18 is a view showing an example of a ranking setting screen in the first embodiment.

FIG. 19 is a flowchart showing a procedure of data processing concerning change in the reference data according to a second embodiment of the present invention.

FIG. 20 is a view showing an example of a change timing setting screen in the second embodiment.

FIG. 21 is a flowchart showing a procedure of data processing concerning change in the reference data in a first modified example.

FIG. 22 is a view showing an example of the ranking screen in the first modified example.

FIG. 23 is a view for explaining the transition of the ranking screen when the reference data is changed in the first modified example.

FIG. 24 is a view showing an example of a change timing setting screen in a second modified example.

FIG. 25 is a view showing an example of a change timing setting screen in a third modified example.

FIG. 26 is a view showing an example of a reference data history screen in a fourth modified example.

FIG. 27 is a view showing an example of a period specification screen in the fourth modified example.

### DETAILED DESCRIPTION OF PREFERRED EMBODIMENTS

Preferred embodiments of the present invention will be described below with reference to the drawings.

### 1. First Embodiment

### 1.1 Configuration of System

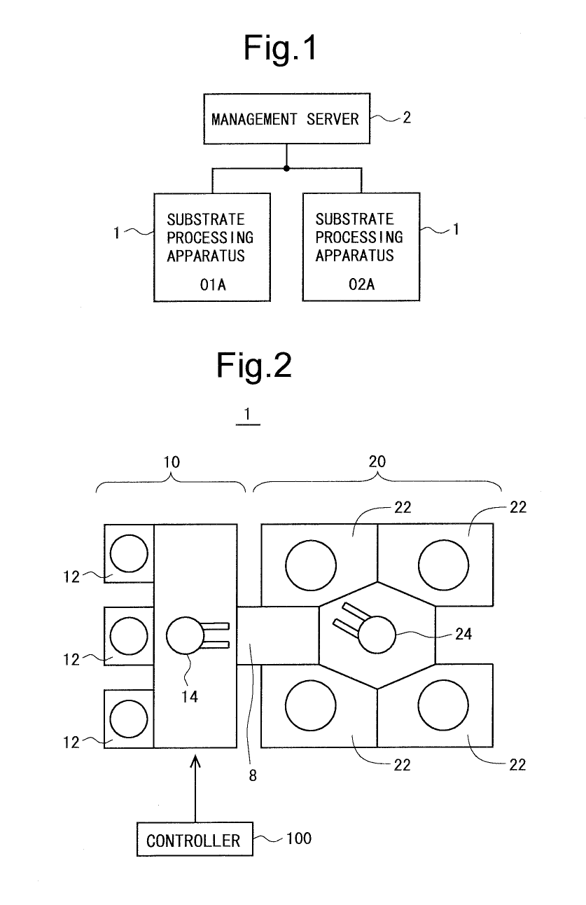

FIG. 1 is a diagram showing a schematic configuration of a substrate processing system (a data processing system) according to a first embodiment of the present invention. The substrate processing system includes a plurality of substrate processing apparatuses 1 and a management server for managing the plurality of substrate processing apparatuses 1. The plurality of substrate processing apparatuses 1 and the management server 2 are connected to each other via a communication line such as a LAN. Note that, unless otherwise noted, it is assumed that two substrate processing apparatuses 1 are provided: one is given an apparatus number “01A” while another is given an apparatus number “02A.”

### 1.1.1 Substrate Processing Apparatus

FIG. 2 is a diagram showing a schematic configuration of a substrate processing apparatus 1 according to the present embodiment. The substrate processing apparatus 1 includes an indexer part 10 and a processing part 20. The indexer part 10 includes a plurality of substrate container holding parts 12 for placing a substrate container (cassette) capable of accommodating a plurality of substrates, and an indexer robot 14 for carrying a substrate out of the substrate container and carrying a substrate into the substrate container. The processing part 20 includes a plurality of processing units 22 for performing processing such as cleaning of substrates using a processing liquid, and a substrate transfer robot 24 for carrying a substrate into the processing unit 22 and carrying a substrate out of the processing unit 22. The number of processing units 22 is, for example, 12. In this case, for example, a tower structure formed by laminating three processing units 22 is provided at each of four positions around the substrate transfer robot 24 as shown in FIG. 2. Each processing unit 22 is provided with a chamber that is a space for processing the substrate, and the processing liquid is supplied to the substrate in the chamber. Further, the substrate processing apparatus 1 is internally provided with a controller 100 constituted of a microcomputer.

When processing is performed on the substrate, the indexer robot 14 takes the substrate to be processed out of the substrate container placed on the substrate container holding part 12 and transfers the substrate to the substrate transfer robot 24 via a substrate transfer part 8. The substrate transfer robot 24 carries the substrate received from the indexer robot 14 into the target processing unit 22. When the processing on the substrate is completed, the substrate transfer robot 24 takes the substrate out of the target processing unit 22 and transfers the substrate to the indexer robot 14 via the substrate transfer part 8. The indexer robot 14 carries the substrate received from the substrate transfer robot 24 to a target substrate container.

The controller 100 controls operation of an object to be controlled (such as a moving mechanism for moving the indexer robot 14) included in the indexer part 10 and the processing part 20. In addition, the controller 100 accumulates and holds time series data obtained by executing a recipe in this substrate processing apparatus 1, and performs various pieces of data processing using the time series data.

### 1.1.2 Time Series Data

In the substrate processing apparatus 1 according to the present embodiment, time series data is acquired every time a recipe is executed in order to detect abnormality of equipment relating to processing in each processing unit 22, abnormality of processing performed in each processing unit 22, and the like. The time series data acquired in the present embodiment is obtained by measuring various physical quantities (e.g., a flow rate of a nozzle, an internal pressure of a chamber, an exhaust pressure of a chamber, etc.) using a sensor or the like when a recipe is executed, and arranging measurement results in chronological order. In a data processing program to be described later, various physical quantities are processed as values of corresponding parameters, respectively. Note that one parameter corresponds to one type of physical quantity.

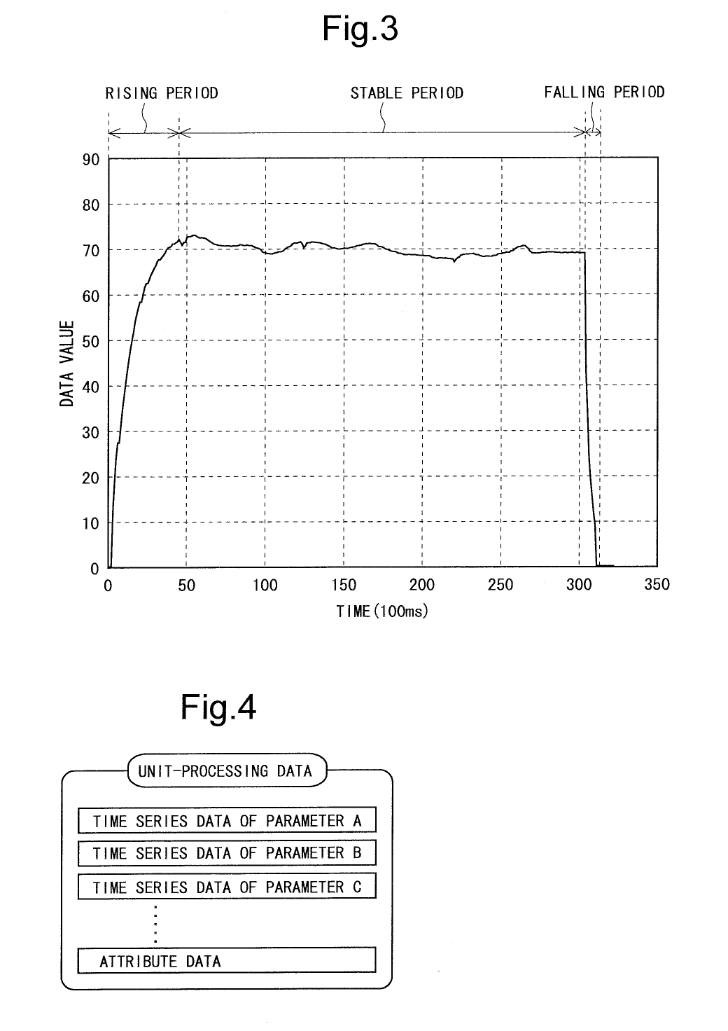

FIG. 3 is a diagram representing a certain time series data by a graph. This time series data is data on a certain physical quantity obtained by processing on one substrate in a chamber in one processing unit 22 when one recipe is executed. Note that, although the time series data is data made up of a plurality of discrete values, two temporally adjacent data values are connected by a straight line in FIG. 3. Meanwhile, when one recipe is executed, time series data on various physical quantities are obtained for each processing unit 22 in which the recipe is executed. Therefore, hereinafter, processing which is performed on one substrate in the chamber in one processing unit 22 when one recipe is executed is referred to as “unit-processing”, and a group of time series data obtained by the unit-processing is called “unit-processing data.” As schematically shown in FIG. 4, one piece of unit-processing data includes time series data on a plurality of parameters and attribute data made up of data on a plurality of items (e.g., processing start time, processing end time, etc.) for specifying the piece of unit-processing data. As for FIG. 4, “parameter A”, “parameter B”, and “parameter C” correspond to different kinds of physical quantities.

For detecting an abnormality in equipment or processing, unit-processing data obtained by executing a recipe should be compared with unit-processing data having an ideal data value as a processing result. More specifically, a plurality of pieces of time series data included in unit-processing data obtained by executing a recipe should be compared with a plurality of pieces of time series data included in unit-processing data each having an ideal data value as a processing result. Therefore, in the present embodiment, in each substrate processing apparatus 1, unit-processing data for comparison with unit-processing data to be evaluated (unit-processing data made up of a plurality of pieces of time series data for comparison with a plurality of pieces of time series data included in the unit-processing data to be evaluated) is defined as reference data for each recipe.

Note that, in the present embodiment, in each of the two substrate processing apparatuses 1, the reference data is determined for each recipe irrespective of the number of processing units 22 (the number of chambers). However, the present invention is not limited thereto. The reference data may be defined for each recipe and for each processing unit 22 (that is, for each processing unit 22 regarding each recipe). In the present embodiment, the reference data is defined for each substrate processing apparatus 1 for each recipe. However, the present invention is not limited thereto. One common reference data for the two substrate processing apparatuses 1 may be defined for each recipe. In this case, the unit-processing data obtained by one specific substrate processing apparatus 1 may be defined as the reference data, and the unit-processing data obtained by any of the two substrate processing apparatuses 1 may be defined as the reference data appropriately.

### 1.1.3 Configuration of Controller of the Substrate Processing Apparatus

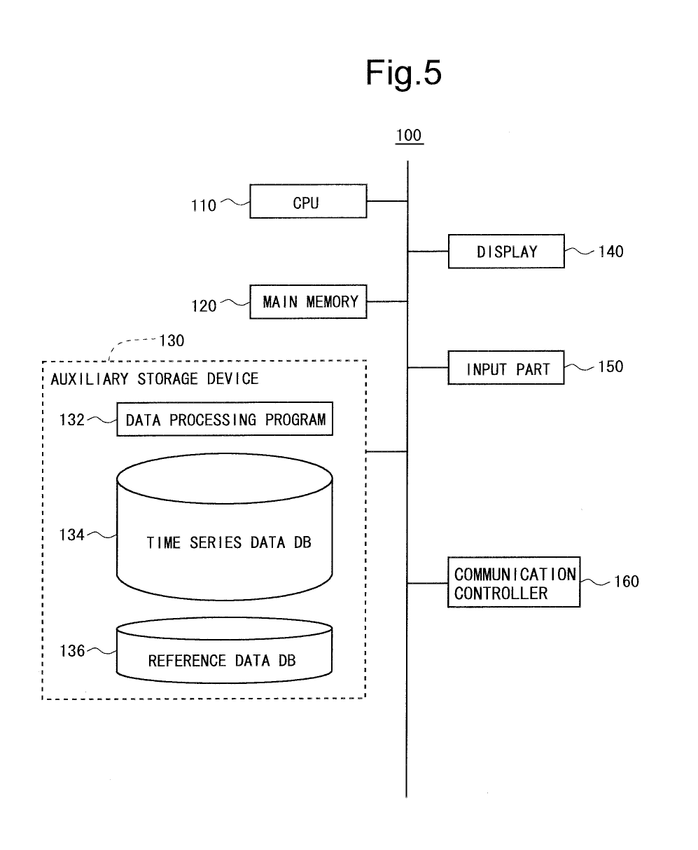

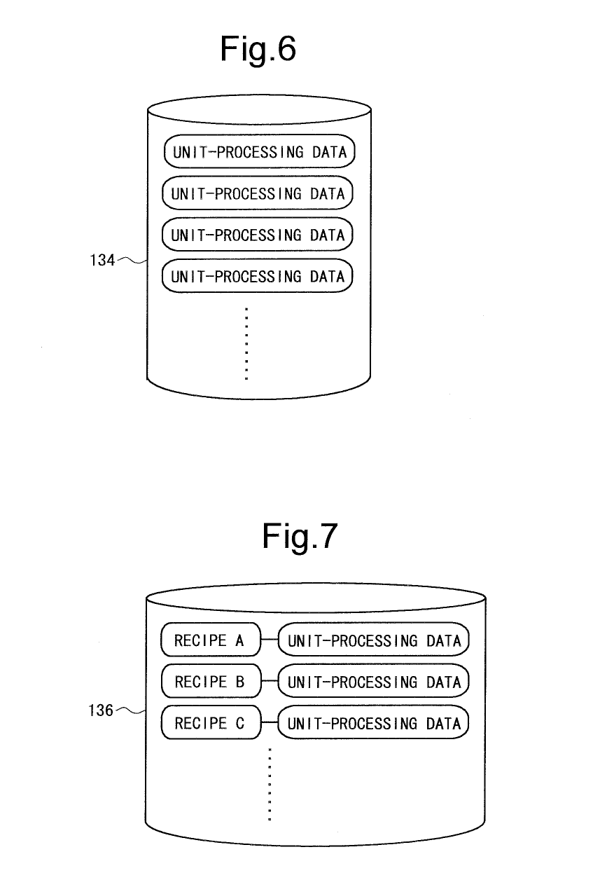

Next, the configuration of the controller 100 of the substrate processing apparatus 1 will be described. FIG. 5 is a block diagram showing a hardware configuration of the controller 100. The controller 100 includes a CPU 110, a main memory 120, an auxiliary storage device 130, a display 140, an input part 150, and a communication controller 160. The CPU 110 performs various arithmetic processing and the like in accordance with a given command. The main memory 120 temporarily stores programs under execution, data, and the like. The auxiliary storage device 130 stores various programs and various pieces of data to be held even when the power is turned off. In the present embodiment, specifically, a data processing program 132 for executing data processing, described later, is stored in the auxiliary storage device 130. Further, the auxiliary storage device 130 is provided with time series data DB 134 and a reference data DB 136. “DB” stands for “database.” As schematically shown in FIG. 6, unit-processing data for a predetermined period is stored in the time series data DB 134. In the reference data DB 136, as schematically shown in FIG. 7, unit-processing data defined as reference data is stored for each recipe (“recipe A”, “recipe B”, and “recipe C” represent different recipes). For example, the display 140 displays various screens for an operator to perform work. The input part 150 is, for example, a mouse, a keyboard, or the like, and accepts an input from the outside by the operator. The communication controller 160 controls data transmission and reception.

When the substrate processing apparatus 1 is activated, the data processing program 132 is read into the main memory 120, and the CPU 110 executes the data processing program 132 read into the main memory 120. Note that the data processing program 132 is provided in the form of being recorded on a recording medium such as a CD-ROM, a DVD-ROM, a flash memory, or the like, or in the form of being downloaded via a network.

### 1.1.4 Configuration of Management Server

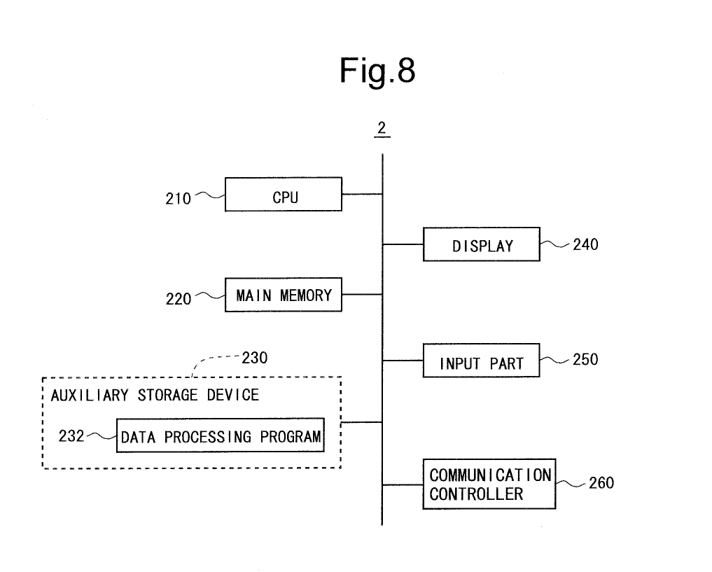

Next, the configuration of the management server 2 will be described. FIG. 8 is a block diagram showing a hardware configuration of the management server 2. The management server 2 includes a CPU 210, a main memory 220, an auxiliary storage device 230, a display 240, an input part 250, and a communication controller 260. The CPU 210, the main memory 220, the auxiliary storage device 230, the display 240, the input part 250, and the communication controller 260 respectively have the same functions as the CPU 110, the main memory 120, the auxiliary storage device 130, the display 140, the input part 150, and the communication controller 160 in the controller 100 of the substrate processing apparatus 1. However, in the auxiliary storage device 230, a data processing program 232 different from the data processing program 132 stored in the auxiliary storage device 130 is stored.

When the management server 2 is activated, the data processing program 232 is read into the main memory 220, and the CPU 210 executes the data processing program 232 read into the main memory 220. Note that the data processing program 232 is provided in the form of being recorded on a recording medium such as a CD-ROM, a DVD-ROM, a flash memory, or the like, or in the form of being downloaded via the network. A program in which the data processing program 132 for the substrate processing apparatus 1 and the data processing program 232 for the management server 2 are integrated may be provided, in the form of being recorded on a recording medium or in the form of being downloaded via the network, to the substrate processing apparatus 1 and the management server 2.

### 1.2 Data Processing Method Concerning Change in Reference Data

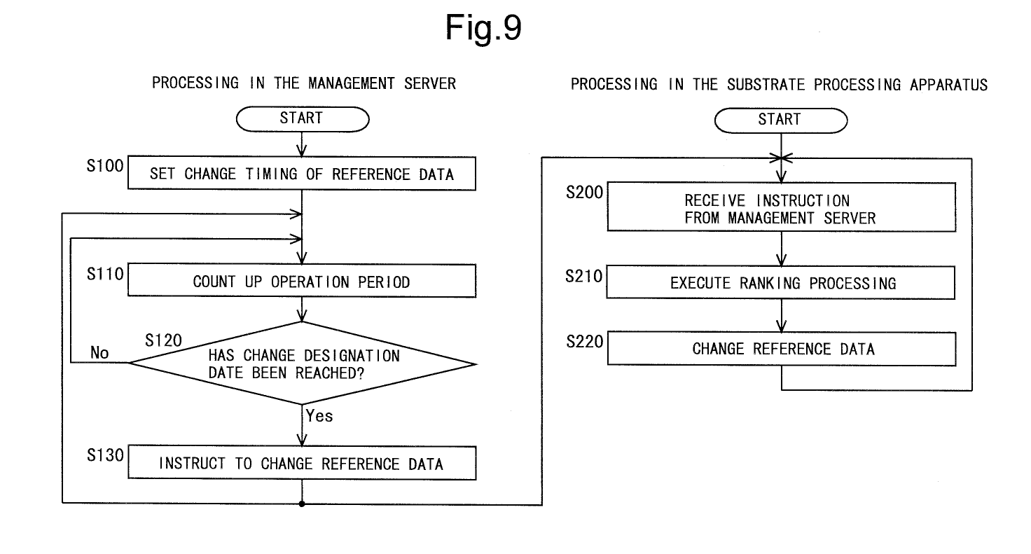

In the substrate processing system according to the present embodiment, the reference data for each recipe in each substrate processing apparatus 1 is changed at designated timing. Hereinafter, with reference to the flowchart shown in FIG. 9, a flow of processing concerning the change in the reference data will be described. In FIG. 9, the processing flow in the management server 2 is shown on the left side and the processing flow in the substrate processing apparatus 1 is shown on the right side. The processing of steps S100 to S130 is achieved by the CPU 210 executing the data processing program 232 in the management server 2, and the processing of steps S200 to S220 is achieved by the CPU 110 executing the data processing program 132 in the substrate processing apparatus 1. Note that, in the following description, unit-processing data to be evaluated is referred to as “evaluation target data.”

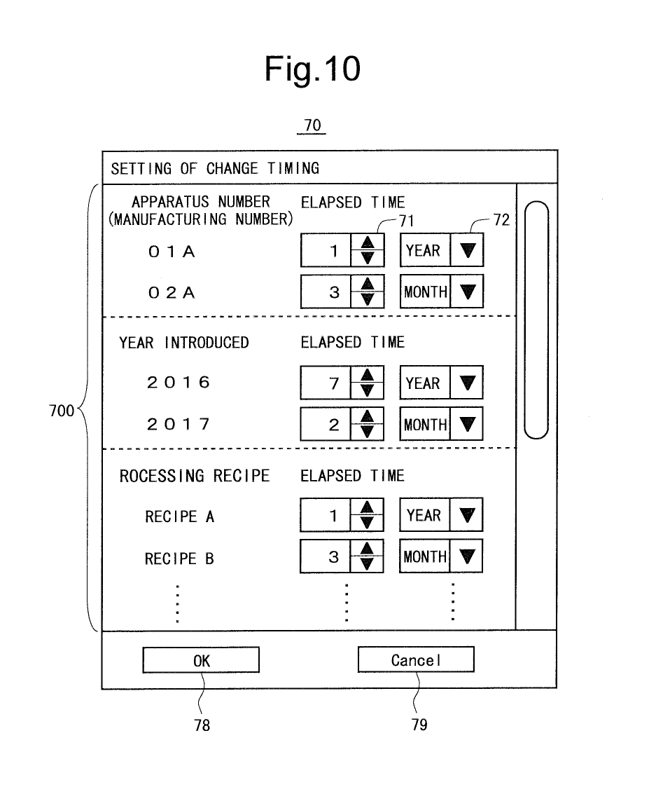

First, in the management server 2, setting of the change timing for the reference data is performed by the operation of the operator (step S100). At that time, a change timing setting screen 70, for example as shown in FIG. 10, is displayed on the display 240 of the management server 2. The change timing setting screen 70 includes a setting area 700, an OK button 78, and a Cancel button 79. The OK button 78 is a button for confirming the setting contents. The Cancel button 79 is a button for canceling the setting contents.

In the setting area 700 of the change timing setting screen 70, it is possible to set the change timing for the reference data concerning three items of “apparatus number”, “year introduced”, and “processing recipe.” For each item, one or more setting targets are provided. For example, regarding the item “year introduced”, two setting targets “2016” and “2017” are provided. setting of the change timing is performed by designating, for each setting target, an elapsed time (i.e., a time interval for changing the reference data) which is a length of a period from a change in the reference data at a certain point in time to the next change in the reference data. Focusing on the item “apparatus number”, it is possible to set the change timing for each apparatus. The apparatus number is a number for uniquely identifying the substrate processing apparatus 1. Focusing on the item “year introduced”, it is possible to set the change timing for each year introduced. The year introduced means a fiscal year in which the substrate processing apparatus 1 is introduced into this substrate processing system. Focusing on the item “processing recipe”, it is possible to set the change timing for each recipe.

As shown in FIG. 10, in the setting area 700, a spin control box 71 and a drop-down list 72 are provided for each setting target. The spin control box 71 is an interface for designating the length of the period to be set. The spin control box 71 is configured so as to be able to increase or decrease the numerical value representing the length of the period. The drop-down list 72 is an interface for designating a unit of a period to be set. The unit that can be designated in this drop-down list 72 is any of “year”, “month”, and “day.”

As described above, in the present embodiment, the reference data is determined for each recipe in each substrate processing apparatus 1. With this in mind, how the reference data is changed based on the contents set on this change timing setting screen 70 will be described.

In the example shown in FIG. 10, regarding the item “apparatus number”, the elapsed time is set to “1 year” for the setting target “01A.” In a case in which such a setting has been made, in the substrate processing apparatus 1 with the apparatus number “01A”, the reference data is changed every one year for all recipes. Further, in the example shown in FIG. 10, regarding the item “year introduced”, the elapsed time is set to “7 days” for the setting target “2016.” In a case in which such a setting has been made, in the substrate processing apparatus 1 that is introduced in the year 2016, the reference data is changed every seven days for all recipes. Moreover, in the example shown in FIG. 10, regarding the item “processing recipe”, the elapsed time for the setting target “recipe A” is set to “1 year.” In a case in which such a setting has been made, in all the substrate processing apparatuses 1, the reference data for the recipe named “recipe A” is changed every one year.

From the above, in the example shown in FIG. 10, for example, the reference data for the recipe named “recipe A” in the substrate processing apparatus 1 introduced in the year 2016 with the apparatus number “01A” is changed at the timing of 7 days and the timing of one year. Further, for example, the reference data for the recipe named “recipe A” in the substrate processing apparatus 1 introduced in the year 2017 with the apparatus number “02A” is changed at the timing of two months, the timing of three months, and the timing of one year.

Note that the configuration may be such that the elapsed time can be set to “0” or “blank” on the change timing setting screen 70 and the setting target with the elapsed time set to “0” or “blank” is ignored at the time of processing in step S120 described later. In addition, when a configuration in which the reference data is defined for each processing unit 22 is adopted, it may be possible to set the change timing for each apparatus and for each processing unit 22.

With respect to the flow shown in FIG. 9, after the change timing for the reference data has been set using the change timing setting screen 70 as described above, the management server 2 counts up the operation period (step S110). Specifically, a variable (hereinafter referred to as “operation period variable”) CntD for counting the operation period is prepared in the data processing program 232, and the value of the operation period variable CntD is incremented by one every time one day passes.

When the value of the operation period variable CntD is incremented by one, for each setting target, it is determined whether or not the date on which the reference data is to be changed (hereinafter referred to as “change designation date”) has been reached, based on setting contents on the change timing setting screen 70 (step S120). As a result of the determination, when there is a setting target whose change designation date has been reached, the processing proceeds to step S130. On the other hand, when there is no setting target whose change designation date has been reached, the processing returns to step S110.

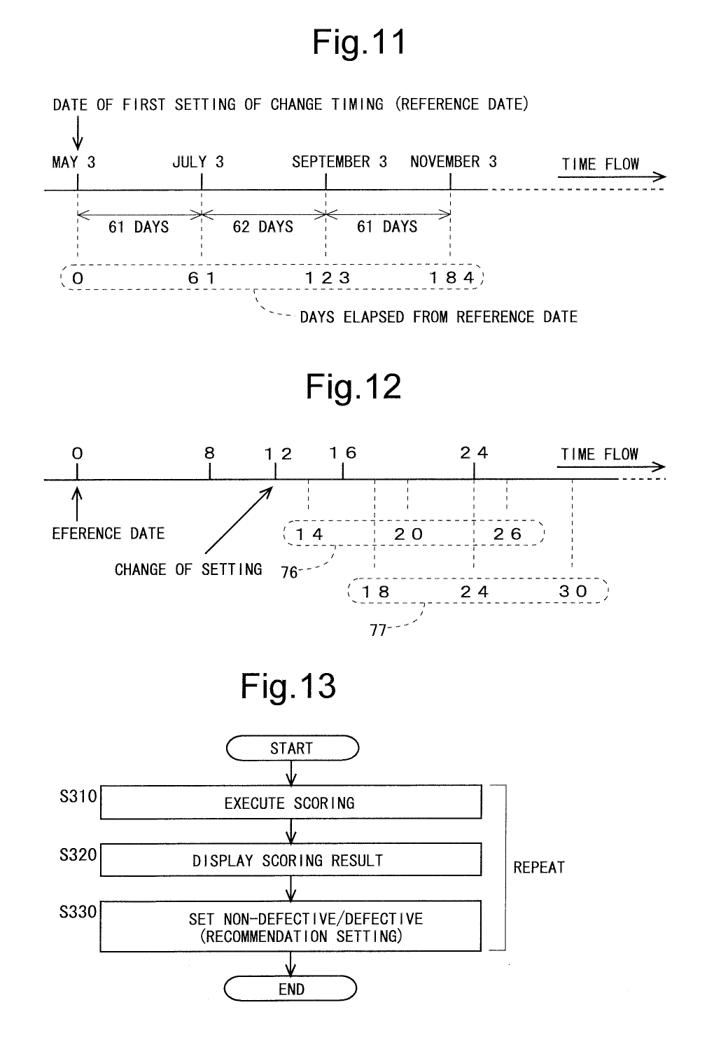

With reference to FIG. 11, an example of a specific method for determining whether or not the change designation date has been reached will be described here. However, the present invention is not limited thereto. It is assumed count of the operation period variable CntD is performed using the date on which the change timing is first set as a reference date. Here, in the example shown in FIG. 10, attention is focused on the setting target “2017” out of the item “year introduced.” For the focused setting target, the elapsed time is set to “February.” At this time, for example, in a case in which the reference date is May 3 of a certain year, as shown in FIG. 11, the change designation date for the focused setting target is the date every two months from May 3 (i.e. July 3, September 3, November 3, . . . ). From the information of the change designation date and the information of the reference date, the number of days elapsed from the reference date can be obtained for each change designation date. For example, as for September 3 of the same year as the reference date, the number of days since the reference date is 123. Since the number of days elapsed from the reference date to each change designation date can be obtained as thus described, it is possible to determine whether or not the change designation date has been reached by comparing the number of days elapsed with the value of the operation period variable CntD. For example, on July 3, the value of the operation period variable CntD becomes “61”, and therefore it can be determined that the change designation date has been reached for the corresponding setting target.

Meanwhile, after the change timing has been first set, the setting change of the change timing may be made for each setting target. How the change designation date changes in accordance with the setting change of the change timing in such a case will be described with reference to FIG. 12. It is assumed here that the change timing (elapsed time) for a certain setting target has been changed from “8 days” to “6 days.” Further, it is assumed that the setting change was made after the lapse of 12 days from the reference date. In this case, at the point in time when the change timing is first set, the change designation date for the focused setting target becomes the date every eight days from the reference date (the number of days elapsed from the reference date is 8, 16, 24, . . . ). In this state, as described above, the setting change is made after the lapse of 12 days from the reference date. At this time, since the latest change in the reference data was made 8 days after the reference date, for example, as denoted by reference numeral 76 in FIG. 12, the date every six days from the day after the eight days from the reference date (the number of days elapsed from the reference date is 14, 20, 26, . . . ) can be defined as the change designation date. Further, for example, as denoted by reference numeral 77 in FIG. 12, the date every six days from the date on which setting change is changed (the number of days elapsed from the reference date is 18, 24, 30, . . . ) can also be defined as the change designation date. In this manner, the processing in the case where the setting change of the change timing is made is not particularly limited, and the change designation date may be changed in accordance with an appropriately defined rule.

With respect to the flow shown in FIG. 9, in step S130, the management server 2 instructs the substrate processing apparatus 1 that needs to change the reference data to change the reference data. At this time, if the setting target concerning the item “processing recipe” has reached the change designation date, changing the reference data for the target recipe is instructed. In contrast, if the setting target concerning the item “apparatus number” or the item “year introduced” has reached the change designation date, changing the reference data for all the recipes is instructed.

Thereafter, in the management server 2, the processing returns to step S110. On the other hand, the substrate processing apparatus 1 that needs to change the reference data receives an instruction from the management server 2 (step S200). The substrate processing apparatus 1 that receives the instruction to change the reference data performs ranking processing for determining the unit-processing data to be set as the reference data after change (step S210). The ranking processing in the present embodiment is a series of processing to perform, based on three indices, ranking on a plurality of pieces of unit-processing data obtained by executing a recipe for which the reference data is to be changed. Note that a detailed description of the ranking processing will be given later.

In the substrate processing apparatus 1, after completion of the ranking processing, the reference data is changed based on the result of the ranking processing (step S220). Specifically, the unit-processing data corresponding to the target recipe among the unit-processing data held in the reference data DB 136 (see FIG. 7) is rewritten to the unit-processing data ranked as the first in the ranking processing in step S210. In this manner, the unit-processing data ranked as the first in the ranking processing, namely, the unit-processing data having an ideal time series value becomes the reference data after change.

In the substrate processing apparatus 1, after the reference data corresponding to the setting target whose change designation date has been reached is changed, the processing returns to step S200. That is, the substrate processing apparatus 1 comes into the state of waiting for an instruction to change the reference data to be transmitted from the management server 2.

By performing the above processing in the management server 2 and each substrate processing apparatus 1, the reference data for each recipe held in each substrate processing apparatus 1 is changed in accordance with the set change timing.

Meanwhile, in the example shown in FIG. 10, when attention is paid to the reference data for the recipe named “recipe A” in the substrate processing apparatus 1 introduced in the year 2016 with the apparatus number “01A”, two settings, “1 year” and “7 days” have been set as the change timing (elapsed time) for the reference data. In such a case, in the present embodiment, the change in the reference data is performed at the timing of seven days and the timing of one year. However, in such a case, the reference data may be changed only at the timing of seven days. That is, in the case of the example shown in FIG. 10, the reference data may be changed at least every seven days. In this way, the change in the reference data for each recipe may be performed at least at the minimum timing out of the target change timing set on the change timing setting screen 70.

### 1.3 Unit-Processing Data Evaluation Processing

In the present embodiment, in order to make it possible to perform the ranking processing (ranking on a plurality of pieces of unit-processing data), in each substrate processing apparatus 1, every time any recipe is executed, unit-processing data evaluation processing for evaluating unit-processing data obtained by execution of the target recipe is performed. Hereinafter, this unit-processing data evaluation processing will be described with reference to the flowchart shown in FIG. 13. Note that, here, attention is focused on one recipe, and the recipe is referred to as “focused recipe.”

First, the focused recipe is executed in the substrate processing apparatus 1, and scoring is performed based on the evaluation target data obtained from the processing unit 22 in which the focused recipe is executed (step S310). Note that the scoring is processing of making comparison in time series data of each parameter between the evaluation target data and the reference data, and digitizing the result obtained by the comparison. If the focused recipe is executed by the eight processing units, the scoring is performed based on each of the eight pieces of evaluation target data obtained from the eight processing units 22 (i.e., the scoring is performed for each unit-processing), so that eight scoring results are obtained. In the scoring, “non-defective” or “defective” is determined for a plurality of evaluation items. This determination is made, for each parameter, by comparing an inspection value, obtained based on the time series data included in the evaluation target data and the time series data included in the reference data, with a threshold corresponding to the inspection value (substantially, the determination is made by comparing the time series data included in the evaluation target data with the time series data included in the reference data). In this regard, when the inspection value exceeds the threshold, the corresponding evaluation item is determined to be “defective.” Note that a plurality of evaluation items may be provided for one parameter. In the present embodiment, the scoring result of each piece of evaluation target data is represented in a mode in which the denominator is taken as the total number of evaluation items and the numerator is taken as the number of evaluation items determined as defective.

Examples of evaluation items are listed below.

### Example 1

An average value of time series data in a stable period (see FIG. 3) concerning a certain parameter

### Example 2

The maximum value of time series data in the stable period (see FIG. 3) concerning a certain parameter

### Example 3

A length of a rising period (see FIG. 3) concerning a certain parameter

Concerning the evaluation item of Example 1, “the difference between the average value of the time series data included in the evaluation target data and the average value of the time series data included in the reference data” in the stable period concerning the target parameter is the above inspection value. Concerning the evaluation item of Example 2, “the difference between the maximum value of the time series data included in the evaluation target data and the maximum value of the time series data included in the reference data” in the stable period concerning the target parameter is the above inspection value. Concerning the evaluation item of Example 3, “the difference between the length of the rising period for the time series data included in the evaluation target data and the length of the rising period for the time series data included in the reference data” is the above inspection value.

Meanwhile, at the time of the scoring, each time series data may be normalized. For example, with respect to each parameter, linear conversion may be performed on the time series data included in the evaluation target data so that the maximum value of the time series data included in the reference data is converted into 1 and the minimum value thereof is converted into 0. Although the time series data on each of a plurality of parameters is generally included in the evaluation target data, the time series data on each of only some parameters may be normalized. By normalizing the time series data as necessary, it is possible to more suitably calculate an evaluation value described later.

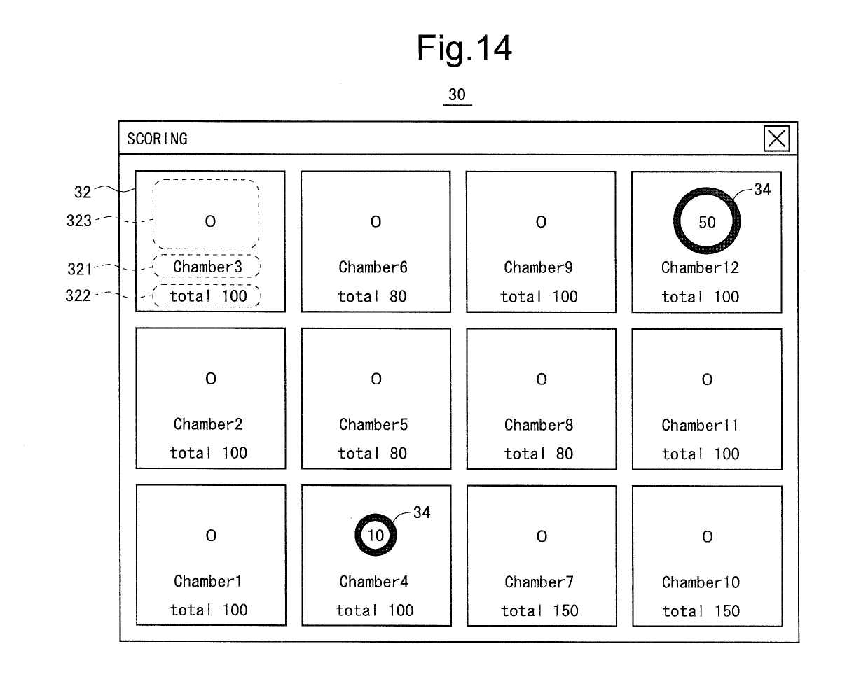

After the scoring is completed, the result of the scoring is displayed (step S320). In this regard, firstly, the scoring screen 30 showing the outline of the scoring result, for example as shown in FIG. 14, is displayed on the display 140. The scoring screen 30 is provided with buttons 32 in number equal to the number of processing units 22. In the button 32, a processing unit name display area 321, a processed number display area 322, and an error number display area 323 are provided. In the processing unit name display area 321, the name of the corresponding processing unit 22 is displayed. In the processed number display area 322, the total number of substrates processed within a predetermined period in the chamber in the corresponding processing unit 22 is displayed. In the error number display area 323, the number of generated error cases is displayed. For the processing unit 22 in which an error has occurred, a circle having a size corresponding to the number of error cases is displayed in the error number display area 323 as denoted by reference numeral 34.

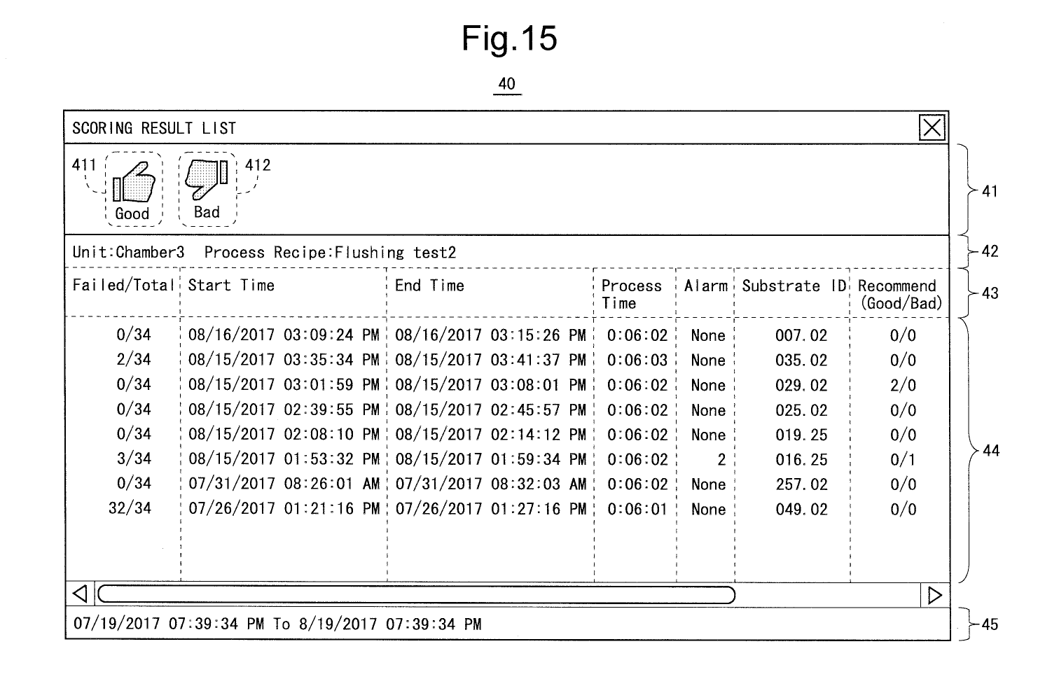

When any one of the buttons 32 on the scoring screen as described above is pressed, a screen showing the scoring result of the unit-processing executed by the corresponding processing unit 22 is displayed. Then, when one unit-processing is selected on the screen displayed, a scoring result list screen 40, which displays a lift of scoring results for the recipe corresponding to the selected unit-processing, for example as shown in FIG. 15, is displayed on the display 140.

As shown in FIG. 15, the scoring result list screen includes a button display area 41, a search target display area 42, an item name display area 43, a result display area 44, and a period display area 45. In the button display area 41, a Good button 411 and a Bad button 412 are provided.

In the search target display area 42, the name of the processing unit 22 to be searched and the name of the recipe to be searched (in this case, the focused recipe) are displayed. In the example shown in FIG. 15, it is grasped that the name of the processing unit 22 to be searched is “Chamber3” and the name of the recipe to be searched is “Flushing test2.”

In the item name display area 43, the item name of the content (attribute data) to be displayed in the result display area 44 is displayed. “Failed/Total” is an item name representing the scoring result. Note that “Failed” corresponds to the number of evaluation items determined to be defective, and “Total” corresponds to the total number of evaluation items. “Start time” is an item name representing the start time of the focused recipe. “End time” is an item name representing the end time of the focused recipe. “Process time” is an item name representing the processing time of the focused recipe. “Alarm” is an item name representing the number of alarms generated at the time of executing the focused recipe. “Substrate ID” is an item name representing a number for uniquely identifying a substrate (wafer) on which processing based on the focused recipe has been performed. “Recommend (Good/Bad)” is an item name representing the recommendation degree described later. Note that “Good” corresponds to a value representing the degree of high evaluation (hereinafter referred to as “Good value”), and “Bad” corresponds to a value representing the degree of low evaluation (hereinafter referred to as “Bad value”). The recommendation degree is made up of these Good value and Bad value.

In the result display area 44, attribute data (various pieces of information, scoring results, etc.) of the unit-processing data matching a search condition is displayed. In the example shown in FIG. 15, attribute data of each of eight pieces of unit-processing data is displayed in the result display area 44. The operator can select one piece of attribute data (one row) from the pieces of attribute data displayed in the result display area 44.

In the period display area 45, a preset search target period is displayed. The attribute data of the unit-processing data obtained by executing the focused recipe in this search target period is displayed in the result display area 44. In the example shown in FIG. 15, it is grasped that the search target period is one month from 7:39:34 pm on Jul. 19, 2017 to 7:39:34 pm on Aug. 19, 2017.

A function of each button provided in the button display area 41 will be described here. The Good button 411 is a button for the operator to press when it is desired to raise the evaluation value of the unit-processing data corresponding to the attribute data selected in the result display area 44. The Bad button 412 is a button for the operator to press when it is desired to lower the evaluation value of the unit-processing data corresponding to the attribute data selected in the result display area 44. Note that the evaluation value will be described later.

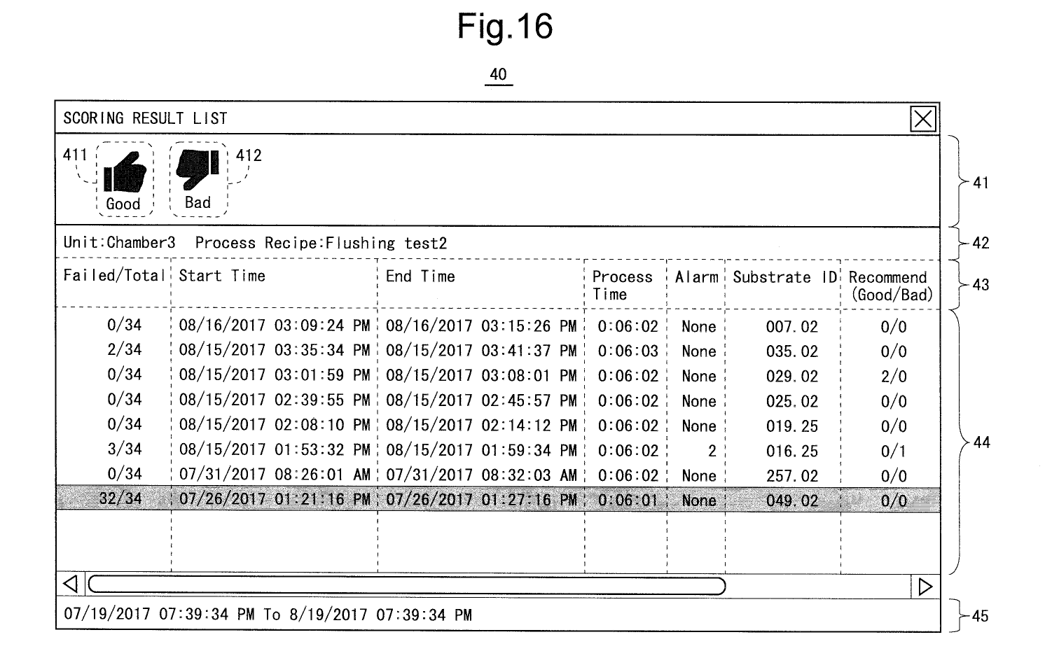

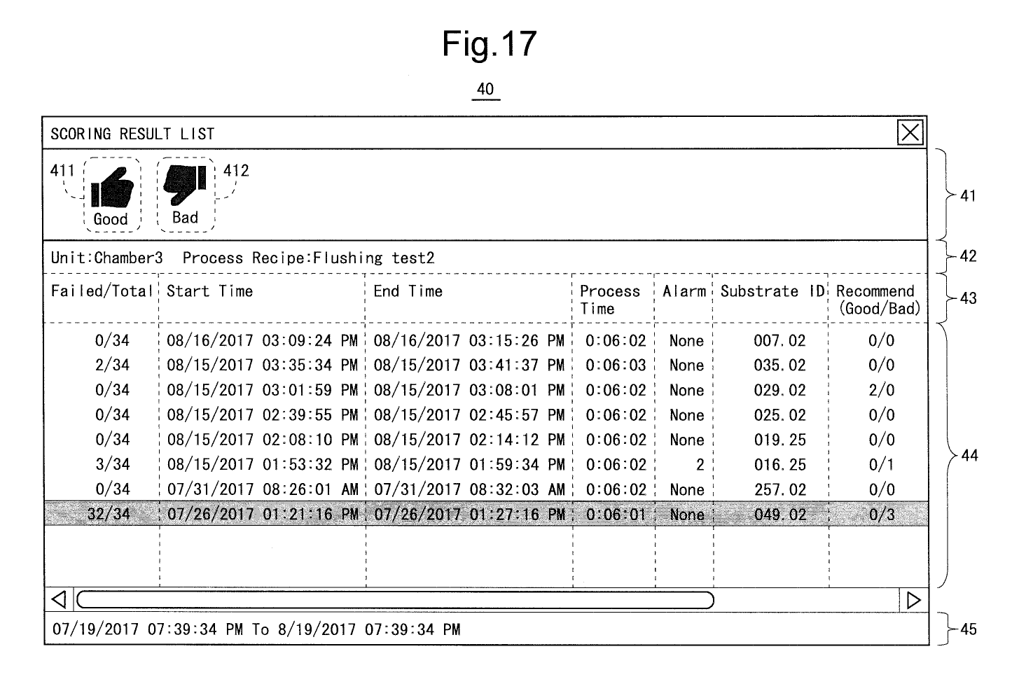

After displaying the scoring result list screen 40, setting (recommendation setting) of the recommendation degree representing the degree of recommending each piece of unit-processing data as reference data is performed as necessary (step S330). The recommendation setting is performed by pressing the Good button 411 or the Bad button 412 in a state where the attribute data corresponding to the unit-processing data to be set among the attribute data displayed in the result display area 44 is selected. At that time, the operator presses the Good button 411 when the unit-processing data to be set is preferable as the reference data, and the operator presses the Bad button 412 when the unit-processing data to be set is not preferable as the reference data. In this regard, immediately after the displaying of the scoring result list screen 40, the Good button 411 and the Bad button 412 are in an un-selectable state. When the operator selects any of the attribute data displayed in the result display area 44 in this state, the corresponding attribute data comes into a selected state and the Good button 411 and the Bad button 412 come into the selectable state as shown in FIG. 16. The operator presses the Good button 411 or the Bad button 412 in this state to add the Good value and the Bad value. For example, when the Bad button 412 is pressed three times from the state shown in FIG. 16, the Bad value of the selected attribute data is “3” as shown in FIG. 17. As described above, the scoring result list screen 40 is configured such that the recommendation degree can be changed from the outside. Note that specifically what value is to be set for the Good value or the Bad value is determined considering, for example, the scoring result, the number of alarms, the state of the resultant object (substrate) obtained in the corresponding unit-processing (e.g., the number of particles, the number of defects, collapse rate), and the like. In addition to the Good button 411 and the Bad button 412, a button for reducing the Good value and a button for reducing the Bad value may be provided.

The processing of step S310 to step S330 is performed every time a recipe is executed. Accordingly, the processing of step S310 to step S330 is repeated during a period in which the substrate processing apparatus 1 is running.

Note that, although the description has been given on the assumption that the scoring result list screen 40 is displayed on the display 140 of the controller 100 included in the substrate processing apparatus 1, the configuration may be such that the display 140 of the management server 2 displays the scoring result list screen 40 for respective substrate processing apparatus 1. The same is true for the scoring screen 30.

### 1.4 Ranking Processing

Next, the ranking processing (step S210 in FIG. 9) will be described. As described above, the ranking processing is a series of processing to perform, based on three indices, ranking on a plurality of pieces of unit-processing data obtained by executing a recipe. The rank of each piece of unit-processing data is determined by an evaluation value (total score) calculated based on the three indices. In the present embodiment, as the three index values for calculating the evaluation value, there are used a value based on the above-mentioned recommendation degree (hereinafter referred to as “recommended value”), a value based on the scoring result (hereinafter referred to as “scoring result value”), and a value based on the number of occurrence of alarms (or presence or absence of an alarm) (hereinafter referred to as “alarm value”). A specific way to obtain the evaluation value will, be described later. In the ranking processing, a plurality of pieces of unit-processing data within the search target period are ranked based on the evaluation value.

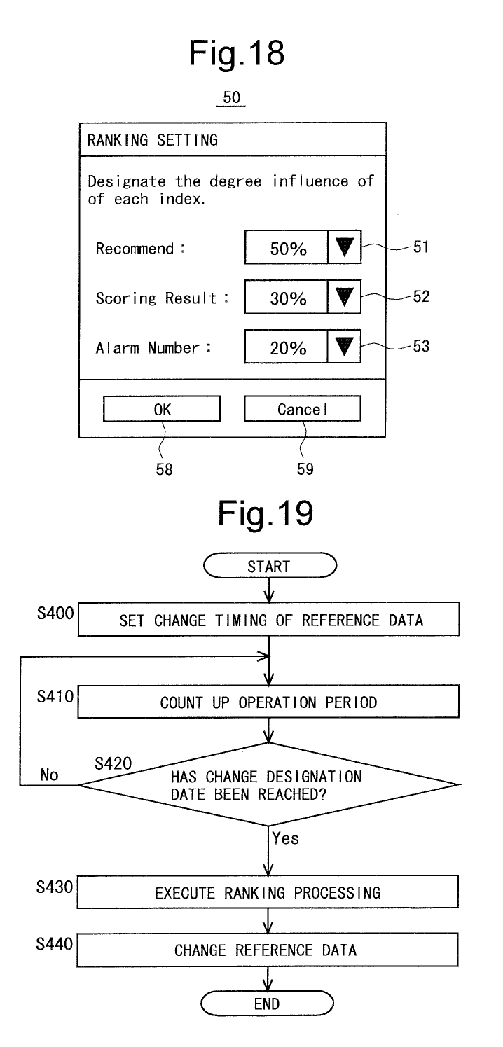

A setting necessary for executing the ranking processing should be performed at an appropriate timing before the ranking processing is actually executed. This setting is performed by the operator's operation using the ranking setting screen 50, for example as shown in FIG. 18. Note that, this setting may be performed in each substrate processing apparatus 1, and this setting may be performed in the management server 2. As shown in FIG. 18, this ranking setting screen 50 includes an OK button 58, a cancel button 59, and three drop-down lists 51 to 53 for setting the influence degree (degree of contribution) of each of the above three index values at the time of calculating the evaluation value for determining the rank of each piece of unit-processing data. The drop-down list 51 is an interface for setting the influence degree of the recommended value. The drop-down list 52 is an interface for setting the influence degree of the scoring result value. The drop-down list 53 is an interface for setting the influence degree of the alarm value. The OK button 58 is a button for confirming the setting contents. The Cancel button 59 is a button for canceling the setting contents (the contents having been set using the drop-down lists 51 to 53).

For the drop-down lists 51 to 53, it is possible to set the influence degree at a step of 1%, for example. However, it is also possible to set the influence degree at a step of 5% or 10%. For the one that is not to be used as an index value at the time of calculating the evaluation value, it is possible to set the influence degree to 0%.

Meanwhile, when the setting value in the drop-down list 51 is defined as a “first setting value”, the setting value in the drop-down list 52 is defined as a “second setting value”, and the setting value in the drop-down list 53 is defined as a “third setting value”, it is preferable to automatically adjust the values such that the sum of the first setting value, the second setting value, and the third setting value becomes 100%. In this regard, the configuration may be such that, when values are set for two drop-down lists after the displaying of the ranking setting screen 50, the value of the remaining drop-down list is set automatically. In this case, for example, when the setting of “first set value=50, second set value=30” is made, the third set value is automatically set to “20.” Alternatively, the configuration may be such that, when the value for any one drop-down list is changed in a state where values for the three drop-down lists have already been set, the values for the remaining two drop-down lists are automatically changed while maintain the ratio thereof. In this case, for example, when the first setting value is changed to “55” in a state where “first setting value=70, second setting value=20, and third setting value=10” has been set, the second setting value is automatically changed to “30”, and the third setting value is automatically changed to “15.”

Note that, the configuration may be such that, such setting that the sum of the first set value, the second set value and the third set value exceeds 100% is accepted and internal processing is performed so as to make the sum be 100% while maintaining the ratio. Further, the configuration may be such that, when such setting that the sum of the first set value, the second set value and the third set value exceeds 100% is performed, a message indicating “the sum exceeds 100%” is displayed to prompt resetting.

In the ranking processing, all pieces of unit-processing data, obtained from each processing unit 22 by the focused recipe being executed in the search target period, become evaluation target data. First, the above recommended value is obtained for each piece of evaluation target data which can be candidates for reference data. When the Good value is represented as CntG and the Bad value is represented as CntB, a recommended value V(R) is calculated by the following Formula (1), for example.

V(R)=(CntG−CntB)×100/(CntG+CntB) (1)

Here, when “CntG=0” and “CntB=0”, “V(R)=0” is set.

Next, the above alarm value is obtained for each piece of evaluation target data. For the alarm value V(A), for example, “V(A)=100” is set when the number of alarms is 0 (indicated as “None” on the scoring result list screen 40), and “V(A)=−100” is set when the number of alarms is 1 or more.

Next, the above scoring result value V(S) is obtained for each piece of evaluation target data. When the total number of evaluation items is represented as Nt and the number of evaluation items determined as defective is represented as Nf, the scoring result value V(S) is calculated by the following Formula (2), for example.

V(S)=(Nt−2×Nf)×100/Nt (2)

After the recommended value V(R), the alarm value V(A), and the scoring result value V(S) have been obtained as described above, the above evaluation value (total score) is calculated for each piece of evaluation target data. When the values (proportions) of the drop-down lists to 53 set by the ranking setting screen 50 are respectively represented as P1 to P3, the evaluation value (total score) Vtotal is calculated by the following Formula (3).

Vtotal=V(R)×P1+V(S)×P2+V(A)×P3 (3)

After the calculation of the evaluation values for all pieces of unit-processing data (evaluation target data) that can be candidates for the reference data, ranking on the unit-processing data is performed based on the calculated evaluation value. At that time, unit-processing data with a larger evaluation value is ranked higher (a numerical value representing the rank becomes smaller). Therefore, the unit-processing data ranked as the first is the unit-processing data having the largest evaluation value. Based on the result of foregoing ranking processing, as described above, the reference data is changed (step S220 in FIG. 9).

### 1.5 Effects

According to the present embodiment, it is possible to set, for each of a plurality of items, the timing of changing the reference data selected from a plurality of pieces of unit-processing data each including a plurality of pieces of time series data. In each substrate processing apparatus 1, the reference data for each recipe is changed at the timing set by the operator. Therefore, by properly setting the change timing for the reference data in consideration of the usage situation, degree of deterioration, and the like of each substrate processing apparatus 1, it is possible to hold the reference data appropriate for the current state of the substrate processing system. This makes it possible to compare the unit-processing data obtained by executing each recipe with the reference data appropriate for the current state of the substrate processing system, so that the abnormality of the processing executed in the substrate processing apparatus 1 can be detected accurately. As described above, according to the present embodiment, it is possible to perform the abnormality detection using time series data more accurately than before.

Further, according to the present embodiment, the reference data is automatically changed at the timing set on the change timing setting screen. That is, it is unnecessary for the operator to select the unit-processing data to be set as the reference data after change. Therefore, the operation load of the operator is reduced as compared with a configuration in which selection by the operator is required. In addition, inappropriate unit-processing data is prevented from being set as the reference data due to an error in the operator's operation.

### 2. Second Embodiment

### 2.1 Overview

In the first embodiment, it is assumed that the operation is performed in the form of the substrate processing system including a plurality of substrate processing apparatuses 1 and the management server 2. However, the present invention is not limited thereto. So, there will be described an example in which operation is performed by one substrate processing apparatus 1 alone as a second embodiment of the present invention.

The configuration of the substrate processing apparatus 1 in the present embodiment is the same as the configuration of the substrate processing apparatus 1 in the first embodiment (see FIGS. 2 and 5 to 7). However, unlike the first embodiment, the data processing program 132 stored in the auxiliary storage device 130 in the present embodiment is a program for executing a series of processing from step S400 to step S440 in FIG. 19.

### 2.2 Data Processing Method Concerning Change in Reference Data

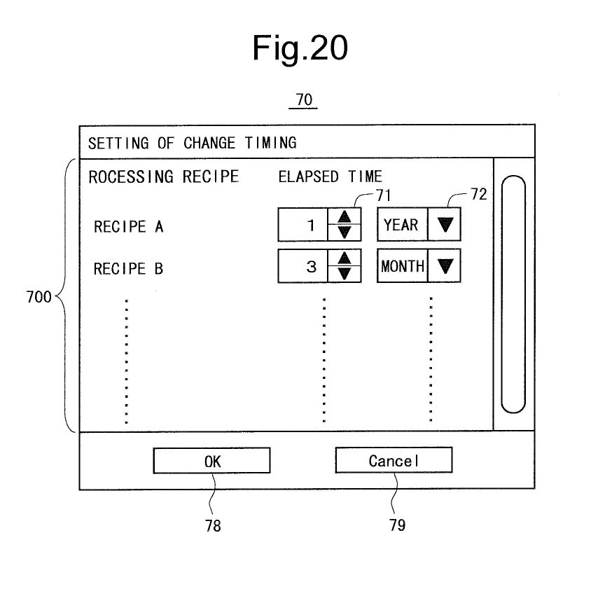

With reference to FIG. 19, a flow of processing concerning the change in the reference data will be described. First, setting of the change timing for the reference data is performed by the operator's operation (step S400). In the present embodiment, since operation is performed by one substrate processing apparatus 1 alone, a change timing setting screen 70, for example as shown in FIG. 20, is displayed on the display 140 of the substrate processing apparatus 1 in step S400. As can be understood from FIG. 20, it is possible to set the change timing for the reference data for each recipe. The operator operates the spin control box 71 and the drop-down list 72 to set the change timing for the reference data for each recipe.

After setting of the change timing for the reference data, the operation period is counted up (step S410). Specifically, the value of the operation period variable CntD prepared by the data processing program is incremented by one every time one day passes. Then, it is determined whether or not the change designation date has been reached for each setting target, based on the setting contents on the change timing setting screen 70 (step S420). As a result of the determination, when there is a setting target whose change designation date has been reached, the processing proceeds to step S430. On the other hand, when there is no setting target whose change designation date has been reached, the processing returns to step S410.

In step S430, the ranking processing is performed as in the first embodiment. The reference data is then changed based on the result of the ranking processing (step S440).

### 2.3 Effects

According to the present embodiment, a similar effect to that in the first embodiment can be obtained in the configuration in which the data processing concerning the change in the reference data is performed by one substrate processing apparatus 1 alone.

### 3. Modified Example

Hereinafter, modified examples of the above embodiments will be described. Note that first to fourth modified examples described below can be applied to any of the first embodiment and the second embodiment.

### 3.1 First Modified Example

In each of the above embodiments, when the reference data is changed, the unit-processing data ranked as the first in the ranking processing is automatically set as the reference data after change. However, the present invention is not limited thereto. The configuration may be such that the unit-processing data to be set as the reference data after change is selected by the operator.

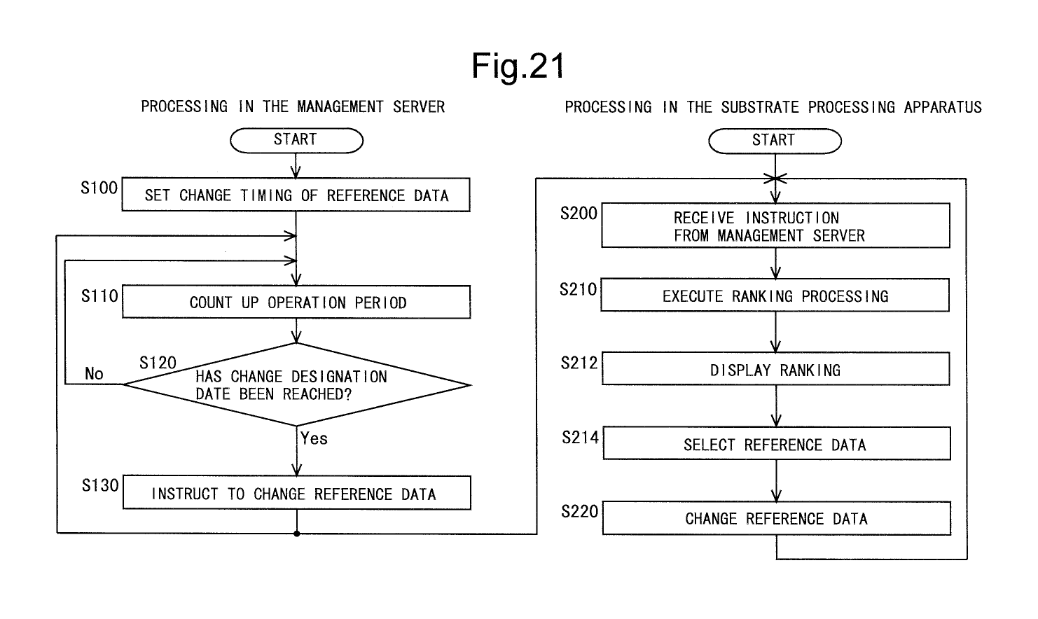

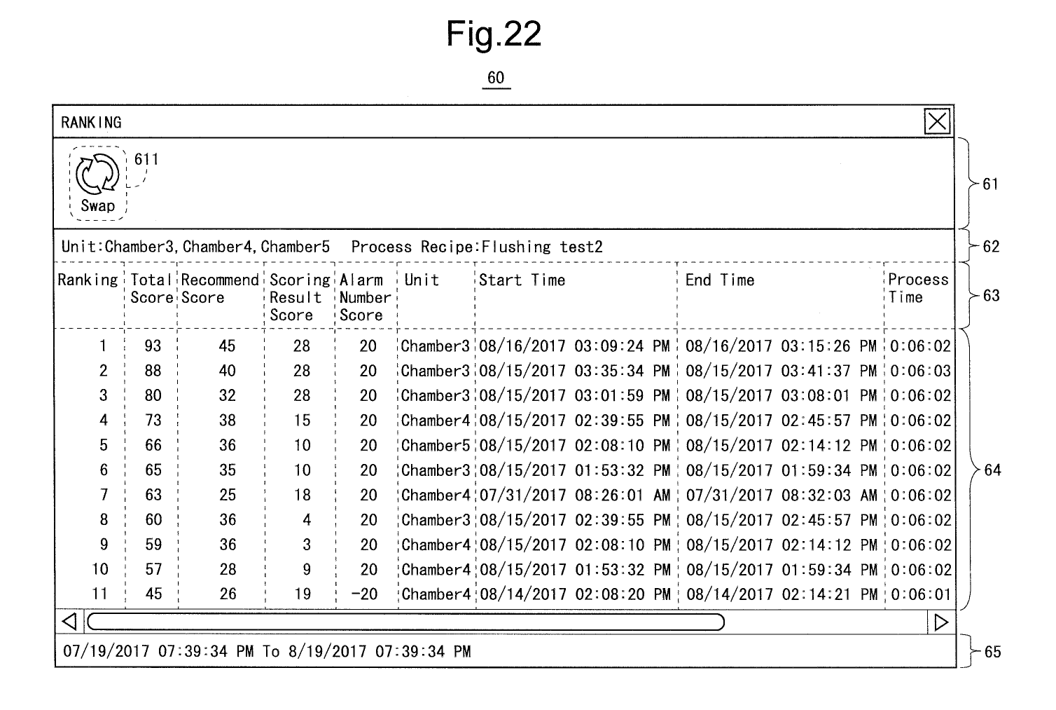

FIG. 21 is a flowchart showing a procedure of data processing concerning change in the reference data in the present modified example. In the present modified example, in each substrate processing apparatus 1, after completion of the ranking processing (step S210), a ranking screen 60, for example as shown in FIG. 22, which shows the result of ranking by the ranking processing is displayed on the display 140 (Step S212). As shown in FIG. 22, attribute data for a plurality of pieces of unit-processing data is displayed on the ranking screen 60 in a ranking format in accordance with the result of the ranking.

The ranking screen 60 includes a button display area 61, a search target display area 62, an item name display area 63, a result display area 64, and a period display area 65. A Swap button 611 is provided in the button display area 61.

In the search target display area 62, the name of the processing unit 22 to be searched and the name of the recipe to be searched (in this case, the focused recipe) are displayed. In the example shown in FIG. 22, it is grasped that the names of the processing units 22 to be searched are “Chamber3”, “Chamber4”, and “Chamber5” and the name of the recipe to be searched is “Flushing test2.” While only the processing unit 22 selected on the scoring screen 30 (see FIG. 14) has been the search target on the scoring result list screen 40 (see FIG. 15), all the processing units 22 for which the focused recipe is executed in the search target period are search targets on the ranking screen 60.

In the item name display area 63, the item name of the content (attribute data) to be displayed in the result display area 64 is displayed. “Ranking” is an item name representing a rank based on the ranking. “Total Score” is an item name representing the evaluation value (total score). “Recommend Score” is an item name representing a value (V(R)×P1) obtained by multiplying the recommended value by the ratio set in the drop-down list 51 of the ranking setting screen 50. “Scoring Result Score” is an item name representing a value (V(S)×P2) obtained by multiplying the scoring result value by the ratio set in the drop-down list 52 of the ranking setting screen 50. “Alarm Number Score” is an item name representing a value (V(A)×P3) obtained by multiplying the alarm value by the ratio set in the drop-down list 53 of the ranking setting screen 50. “Unit” is an item name representing the processing unit. “Start time” is an item name representing the start time of the focused recipe. “End time” is an item name representing the end time of the focused recipe. “Process time” is an item name representing the processing time of the focused recipe.

In the result display area 64, attribute data (various pieces of information, ranks based on ranking, etc.) of the unit-processing data matching a search condition is displayed. As can be grasped from FIG. 22, in the result display area 64, the attribute data of the unit-processing data is displayed in a state sorted from one having a high evaluation value to one having a low evaluation value. Therefore, the unit-processing data corresponding to attribute data displayed on the first row of the result display area 64 is the unit-processing data having the largest evaluation value among the unit-processing data matching the search condition. The operator can select one piece of attribute data (one row) from the pieces of attribute data displayed in the result display area 64. Note that the configuration may be such that only attribute data of the unit-processing data with high evaluation value (for example, the unit-processing data with the first to fifth rank based on the ranking) is displayed on the result display area 64.

As in the period display area 45 of the scoring result list screen 40, the search target period is displayed in the period display area 65. In the example shown in FIG. 22, it is grasped that the search target period is one month from 7:39:34 pm on Jul. 19, 2017 to 7:39:34 pm on Aug. 19, 2017.

After displaying of the ranking screen 60, the reference data after change is selected by the operator (step S214). Specifically, the operator selects attribute data corresponding to unit-processing data to be set as the reference data after change from the attribute data displayed in the result display area 64 on the ranking screen 60. This brings the selected attribute data into the selected state on the ranking screen 60. In this state, the operator presses the Swap button 611 in the button display area 61. As a result, the reference data for the focused recipe is changed (step S220). Specifically, the unit-processing data corresponding to the focused recipe among the unit-processing data held in the reference data DB 136 (see FIG. 7) is rewritten to unit-processing data corresponding to the attribute data in the selected state in the result display area 64.

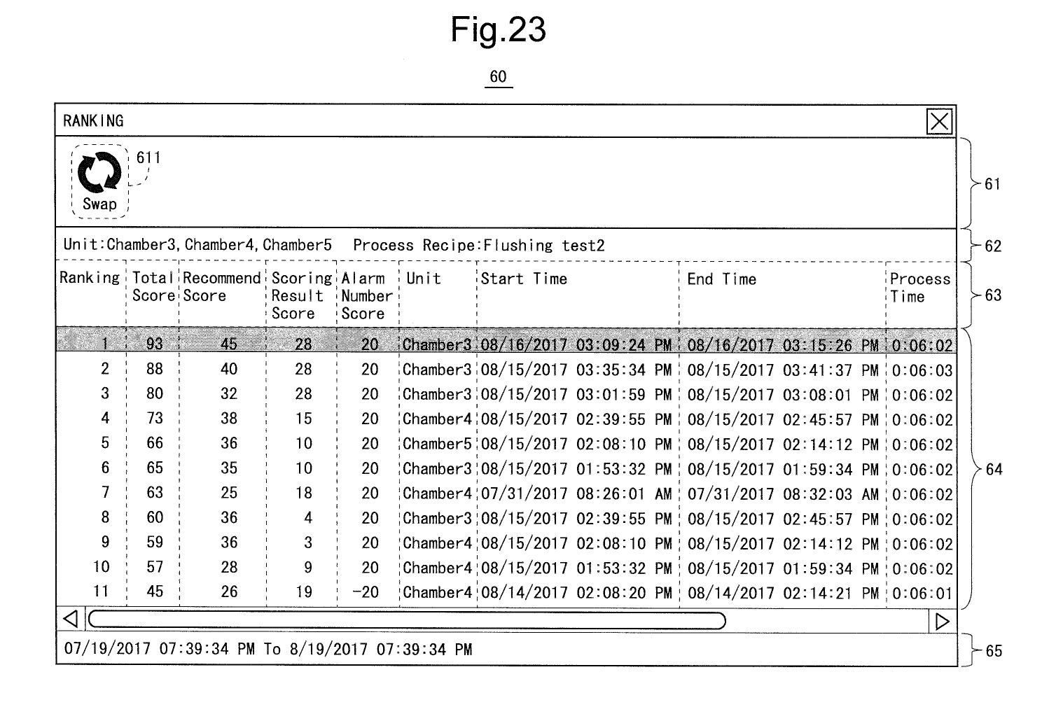

For example, when the operator selects the attribute data on the first row in the result display area 64 while the ranking screen 60 is in the state shown in FIG. 22, the attribute data on the first row comes into the selected state and the Swap button 611 comes into a pressable state as shown in FIG. 23. When the operator presses the Swap button 611 in this state, the reference data for the focused recipe is changed to the unit-processing data corresponding to the attribute data on the first row.

According to the present modified example, it is possible to select any unit-processing data as the reference data after change with reference to the result of the ranking based on the evaluation value (ranking processing). Therefore, it is also possible to select unit-processing data with a rank other than the first rank based on the ranking as the reference data. In this manner, it is possible to select the reference data matching the needs of the user.

### 3.2 Second Modified Example

In each of the above embodiments, the reference data is changed at the change designation date based on the setting contents on the change timing setting screen 70. With respect to this, a function to change the reference data at any timing desired by the user (hereinafter referred to as “optional change function”), such as a function to change the reference data in conjunction with maintenance processing performed irregularly, may be provided. Hereinafter, an example of a specific method for achieving this optional change function will be described.

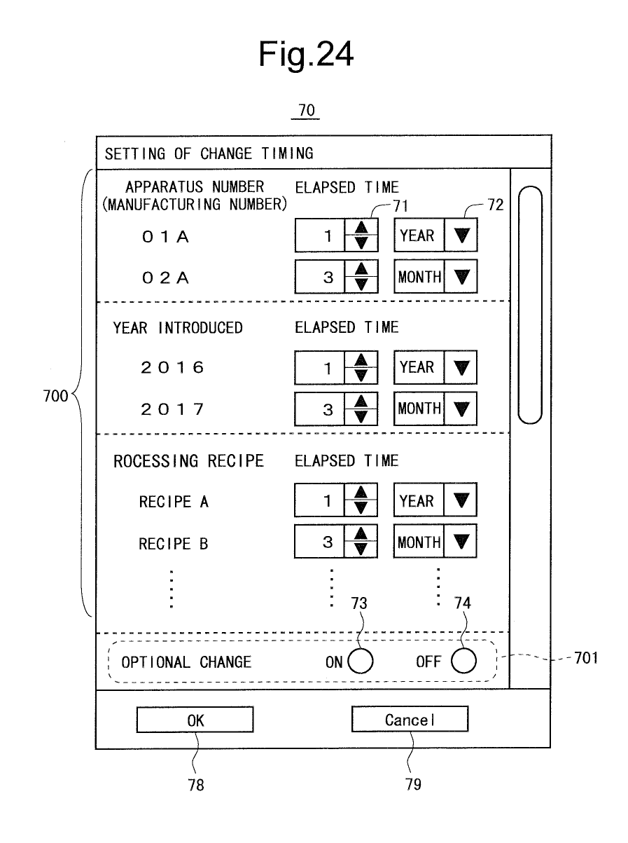

In the present modified example, a software button for the operator to press when the change in the reference data is desired (hereinafter referred to as “reference data change instruction button”) is displayed on the display 140 of the substrate processing apparatus 1. Further, in the setting area 700 of the change timing setting screen 70 in the present modified example, an optional change setting area 701 for setting whether or not to enable the optional change function is provided as shown in FIG. 24. Two radio buttons 73, 74 are provided in the optional change setting area 701. When the radio button 73 is in a selected state, the optional change function is valid, and when the radio button 74 is in the selected state, the optional change function is invalid. Note that the reference data change instruction button corresponds to a change instruction part, and setting the radio button 73 into the selected state corresponds to enabling the change instruction.

When the reference data change instruction button is pressed while the optional change function is valid, the substrate processing apparatus 1 first performs the ranking processing (processing of step S210 in FIG. 9). In this ranking processing, ranking on a plurality of pieces of unit-processing data obtained by executing a recipe is performed based on three indices for every recipe. Then, in the substrate processing apparatus 1, the reference data is changed for each recipe based on the result of the ranking. Specifically, for each recipe, the unit-processing data ranked as the first by the ranking is set as the reference data after change. In this way, when the reference data change instruction button is pressed while the optional change function is valid, the reference data is changed irrespective of the setting contents on the change timing setting screen 70.

In the above configuration, for example, when the user desires to change the reference data each time the maintenance processing is performed, the operator may press the reference data change instruction button each time the maintenance processing is performed after the optional change function has been enabled.

Note that, if the data processing program can detect the pressing of the hardware button, the reference data change instruction button may be achieved by a hardware button instead of a software button.

### 3.3 Third Modified Example

In each of the above embodiments, the change timing is set by designating a time interval (an elapsed time which is a length of a period from a change in the reference data at a certain point in time to the next change in the reference data). However, the present invention is not limited thereto. Setting of the change timing may be performed by designating the number of times of processing.

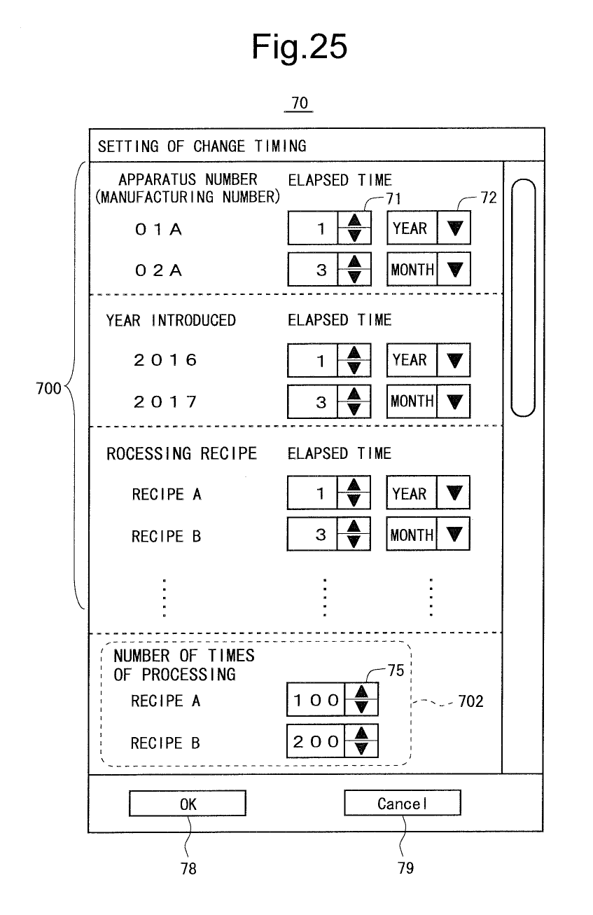

In the present modified example, for example, as shown in FIG. 25, an area 702 for setting the change timing by designating the number of times of processing for each recipe is provided in the setting area 700 of the change timing setting screen 70. In this area 702, there is provided a spin control box 75 configured to increase or decrease the numerical value representing the number of times of processing.

In the above configuration, for example, when the number of times of processing for the recipe A is set to “100” as shown in FIG. 25, the reference data for the recipe A is changed each time the recipe A is executed 100 times in addition to being changed at the change timing based on the designation of the elapsed time.

### 3.4 Fourth Modified Example

According to the above embodiments, the reference data is changed in accordance with the change timing set by the operator. In this regard, although only the latest reference data for each recipe is held in the reference data DB 136 in the above embodiments, past reference data may also be stored in the reference data DB 136. Further, the past reference data can also be stored in a database other than the reference data DB 136. In this manner, the history of the reference data may be left.

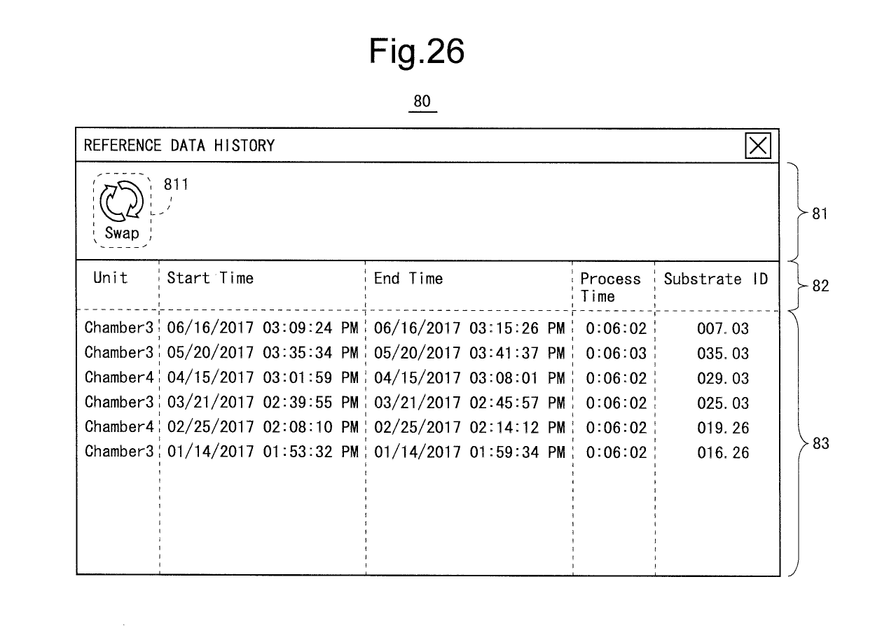

Thus, a function of restoring the past reference data as the current reference data using the history of the reference data may be provided. For example, the configuration may be such that a menu for displaying the history of the reference data is prepared in advance in each substrate processing apparatus 1 (or in the management server 2) and when the menu is selected to specify a recipe, the reference data history screen 80 as shown in FIG. 26 is displayed on the display 140. As shown in FIG. 26, the reference data history screen 80 includes a button display area 81, an item name display area 82, and a history display area 83. In the button display area 81, a Swap button 811 is provided. In the item name display area 82, the item name of the content (attribute data) to be displayed in the history display area 83 (e.g., the item name representing the start time of the specified recipe) is displayed. In the history display area 83, attribute data of past reference data (unit-processing data defined as reference data in the past) for the specified recipe is displayed. In the example shown in FIG. 26, attribute data of the six pieces of past reference data are displayed in the history display area 83. The operator can select one piece of attribute data (one row) from the attribute data displayed in the history display area 83. The Swap button 811 is a button for restoring past reference data (unit-processing data determined in the past as reference data) corresponding to the attribute data selected in the history display area 83 as current reference data.

Immediately after displaying of the reference data history screen 80, the Swap button 811 is in an un-selectable state. When an operator selects one piece of attribute data displayed in the history display area 83 in this state, the target attribute data comes into a selected state and the Swap button 811 comes into a selectable state. When the operator presses the Swap button 811 in this state, regardless of the setting content on the change timing setting screen 70, the reference data is changed to the unit-processing data corresponding to the attribute data selected in the history display area 83. That is, the past reference data corresponding to the attribute data in the selected state in the history display area 83 is restored as the current reference data for the specified recipe.

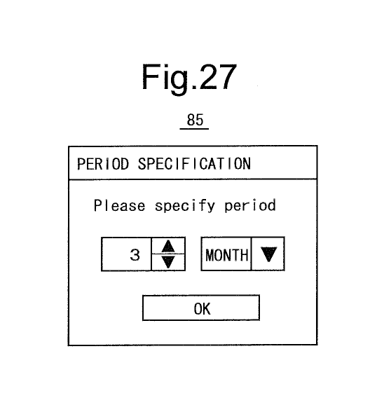

Note that, in connection with the present modified example, the configuration may be such that, a period specification screen 85 as shown in FIG. 27 is displayed on the display 140 to accept specification of a period by the operator, for example, after the recipe has been specified, and the history of the reference data in the case of assuming that the reference data has been changed for each specified period is displayed on the display 140. Thereby, for example, the history of the reference data assuming that the reference data is changed every seven days, the history of the reference data assuming that the reference data is changed every month, the history of the reference data assuming that the reference data is changed every year, and the like are displayed sequentially, and the results of those can be used for analysis of time series data.

Although the present invention has been described in detail above, the above description is illustrative in all aspects and is not restrictive. It is understood that numerous other modifications and variations can be devised without departing from the scope of the present invention.

The present application claims priority to Japanese Patent Application No. 2018-20800 filed on Feb. 8, 2018 entitled “Data Processing Method, Data Processing Apparatus, Data Processing System, and Data Processing Program”, and the entire contents of which are incorporated herein by reference.

What is claimed is:

1. A data processing method for processing a plurality of pieces of unit-processing data by regarding a plurality of pieces of time series data obtained by unit-processing as unit-processing data, the method comprising:
a change timing setting step of setting change timing for reference data which is data selected from the plurality of pieces of unit-processing data and is data to be compared with each piece of unit-processing data; and
a reference data changing step of changing the reference data at the timing set in the change timing setting step.

2. The data processing method according to claim 1, wherein in the reference data changing step, ranking on a plurality of pieces of unit-processing data is performed based on an evaluation value calculated for each piece of unit-processing data, and unit-processing data to be set as the reference data after change is determined based on a result of the ranking.

3. The data processing method according to claim 2, wherein in the reference data changing step, the unit-processing data ranked as the first by the ranking is defined as the reference data after change.

4. The data processing method according to claim 2, wherein the reference data changing step includes
a ranking displaying step of displaying attribute data representing attributes of the plurality of pieces of unit-processing data in a ranking format in accordance with the result of the ranking, and
a reference data selecting step of selecting attribute data of unit-processing data to be set as the reference data after change from the plurality of pieces of attribute data displayed in the ranking display step.

5. The data processing method according to claim 1, wherein in the change timing setting step, setting of the change timing is performed by designating a time interval at which the reference data is changed.

6. The data processing method according to claim 1, wherein the unit-processing is processing executed as one recipe for one substrate by a substrate processing apparatus.

7. The data processing method according to claim 6, wherein in the change timing setting step, setting of the change timing is performed by designating a time interval at which the reference data is changed for each substrate processing apparatus.

8. The data processing method according to claim 6, wherein in the change timing setting step, setting of the change timing is performed by designating a time interval at which the reference data is changed for each year during which the substrate processing apparatus is introduced.

9. The data processing method according to claim 6, wherein in the change timing setting step, setting of the change timing is performed by designating a time interval at which the reference data is changed for each recipe.

10. The data processing method according to claim 6, wherein
the substrate processing apparatus includes a plurality of processing units that processes a substrate, and
in the change timing setting step, setting of the change timing is performed by designating a time interval at which the reference data is changed for each processing unit.

11. The data processing method according to claim 1, wherein,
the unit-processing is processing executed as one recipe for one substrate by a substrate processing apparatus, and
in the change timing setting step, setting of the change timing is performed by designating the number of times of processing for each recipe.

12. The data processing method according to claim 6, wherein
the substrate processing apparatus includes a change instruction part that commands a change of the reference data,
in the change timing setting step, in addition to setting of the change timing, setting as to whether or not to enable a change instruction by the change instruction part is performed, and
when a change instruction by the change instruction part is made while a setting is made to enable the change instruction by the change instruction part in the change timing setting step, the reference data is changed, irrespective of a content of the setting of the change timing.

13. A data processing apparatus for processing a plurality of pieces of unit-processing data by regarding a plurality of pieces of time series data obtained by unit-processing as unit-processing data, the apparatus comprising:
a change timing setting part configured to set change timing for reference data which is data selected from the plurality of pieces of unit-processing data and is data to be compared with each piece of unit-processing data; and
a reference data changing part configured to change the reference data at the timing set by the change timing setting part.

14. The data processing apparatus according to claim 13, further comprising
a history display part configured to display a history screen in which unit-processing data defined as reference data in the past is displayed in a list so that a history of the reference data can be grasped.

15. The data processing apparatus according to claim 14, further comprising
a reference data restoring part configured to change the reference data to unit-processing data defined as reference data in the past,
wherein
the history screen is configured such that any unit-processing data among the unit-processing data displayed in the list is externally selectable, and
the reference data restoring part changes the reference data to the unit-processing data selected on the history screen, irrespective of a content of the setting of the change timing.

16. The data processing apparatus according to claim 13, wherein, the reference data changing part automatically changes the reference data at the timing set by the change timing setting part.

17. A data processing system for processing a plurality of pieces of unit-processing data by regarding a plurality of pieces of time series data obtained by unit-processing as unit-processing data, the system comprising:
a change timing setting part configured to set change timing for reference data which is data selected from the plurality of pieces of unit-processing data and is data to be compared with each piece of unit-processing data;
a reference data changing part configured to change the reference data at the timing set by the change timing setting part.

18. A computer-readable recording medium having recorded therein a data processing program for processing a plurality of pieces of unit-processing data by regarding a plurality of time series data obtained by unit-processing as unit-processing data, wherein the data processing program causes a computer to execute:
a change timing setting step of setting change timing for reference data which is data selected from the plurality of pieces of unit-processing data and is data to be compared with each piece of unit-processing data; and
a reference data changing step of changing the reference data at the timing set in the change timing setting step.
